(19) United States
(12) Patent Application Publication
(10) Pub. No.: US 2024/0084479 A1
(43) Pub. Date: Mar. 14, 2024

(54) DYNAMIC HVPE OF COMPOSITIONALLY GRADED BUFFER LAYERS

(71) Applicant: Alliance for Sustainable Energy, LLC, Golden, CO (US)

(72) Inventors: Kevin Louis SCHULTE, Denver, CO (US); John David SIMON, Austin, TX (US); Aaron Joseph PTAK, Littleton, CO (US)

(21) Appl. No.: 18/261,893

(22) PCT Filed: Jan. 19, 2022
(86) PCT No.: PCT/US22/12932

§ 371 Date: Jul. 18, 2023

Related U.S. Application Data
(60) Provisional application No. 63/138,842, filed on Jan. 19, 2021.

(51) Int. Cl. C30B 25/18; C30B 25/16; C30B 29/40

(52) U.S. Cl. CPC C30B 25/183; C30B 25/16; C30B 29/40

(57) ABSTRACT

Described herein are devices and methods related to compositionally graded buffers (CGB) and methods and/or systems for producing CGBs. CGBs enable the growth of high quality materials that are lattice mismatched to a substrate. More specifically, the present disclosure relates to methods for making CGBs by hydride vapor phase epitaxy (HVPE). HVPE methods using a single chamber for producing a CGB may result in a transience in the CGB layers as the flows supplying the reactants are switched to produce the next subsequent layer in the CGB. In contrast to this static style of grading, the present disclosure describes a dynamic method for producing CGBs, in which multiple growth chambers are utilized.

### CROSS-REFERENCE TO RELATED APPLICATIONS

This application claims priority from U.S. Provisional Patent Application No. 63/138,842, filed on Jan. 19, 2021, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### BACKGROUND

Compositional grading is an epitaxial growth tool that enables access to lattice constants that differ from the substrate and minimizes defect density via controlled relaxation of mismatch strain. Compositionally graded buffers (CGBs) enable many classes of “metamorphic” III-V devices with tunable bandgaps, including multijunction solar cells, light emitting diodes, and photodetectors. CGBs are usually the thickest regions in metamorphic devices, representing a significant cost due to traditionally low deposition rates (˜5 μm/h) for multinary compounds in organometallic vapor phase epitaxy (OMVPE). Faster growth rates can increase throughput and lower cost, but dislocation dynamics models predict that threading dislocation density (TDD) is proportional to growth rate, which could unacceptably decrease material quality. Therefore, improved methods for producing better performing CGBs quickly and economically are needed.

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1 illustrates a composition, according to some embodiments of the present disclosure.

FIG. 2 illustrates a system for making a composition like the composition illustrated in FIG. 1, according to some embodiments of the present disclosure.

FIG. 3 illustrates AFM (top), CL (middle), and TEM (bottom) images for the four CGBs listed in Table 1, according to some embodiments of the present disclosure.

FIG. 4 illustrates an EDS linescan of region B in the 6° A static grade (FIG. 3 bottom) highlighting In/Ga phase separation in the material, according to some embodiments of the present disclosure. A HAADF image of the analyzed region lies in the inset of the graph.

FIG. 5 illustrates TEM EDS linescans of Ga and In concentration for static and dynamic grades grown on 4B substrates, according to some embodiments of the present disclosure. The growth direction is from left to right.

FIG. 6 illustrates: (a) TEM selected area diffraction of a reduced growth rate CGB revealing ordered superlattice spot; (b): (1/2,1̅/2,3/2) scans of graded buffers grown with varying growth rate; and (c) [11̅0]-aligned (004) reciprocal space map for the 20 μm/h grade, according to some embodiments of the present disclosure.

### REFERENCE NUMERALS

| | |
|---|---|
| 100 | composition |
| 110 | substrate |
| 120 | compositionally graded |
| 125 | layer of CGB |
| 125N | cap layer |
| 130 | semiconductor layer |
| 200 | HVPE system |
| 210 | first chamber |
| 220 | second chamber |
| 230 | transfer channel |
| 240 | reactant flow |
| 250 | exhaust |
| 260 | purge channel |
| 270 | holder |

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target.

In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

Among other things, the present disclosure relates to compositionally graded buffers (CGB) and methods and/or systems for producing CGBs. CGBs enable the growth of high quality materials that are lattice mismatched to a substrate. More specifically, the present disclosure relates to methods for making CGBs by hydride vapor phase epitaxy (HVPE). HVPE methods using a single chamber for producing a CGB may result in a transience in the CGB layers as the flows supplying the reactants are switched to produce the next subsequent layer in the CGB. In contrast to this “static” style of grading, the present disclosure describes a “dynamic” method for producing CGBs, in which multiple growth chambers are utilized. In some embodiments of the present, while growth of a first layer of a CGB is performed in the first chamber, the flow rates for the reactants needed for next layer may be set and allowed to equilibrate in the second chamber. Then, when growth of the first layer is complete, the device being synthesized, including the substrate and the first layer of the CGB may be mechanically transferred to the second chamber, where growth of the second layer of the CGB may be completed. Then, while the second layer is being deposited, the flow rates for the reactants needed to deposit the third layer of the CGB may be adjusted in the now available first growth chamber. In this fashion, a multi-layered CGB may be manufactured by repeatedly moving the substrate with the CGB back and forth between the first chamber and the second chamber until the desired structure is realized. This style of grading enables more abrupt compositional steps, a situation which is more beneficial for strain relaxation in a CGB. The concept of two separate chambers may be extended to as many chambers as there are layers in the final device stack, with a single chamber dedicated to the depositing of a single layer. So, in some embodiments of the present disclosure, a continuous HVPE system may have n chambers in series, where n corresponds to the number of layers being deposited by HVPE.

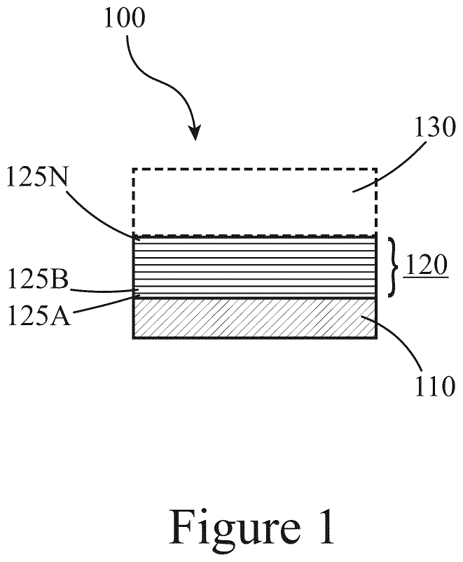

FIG. 1 illustrates a composition 100, according to some embodiments of the present disclosure. In some embodiments of the present disclosure, such a composition 100 may be used in a solar cell, a light-emitting diode, a display, and/or any other suitable optoelectronic device. The exemplary composition 100 shown in FIG. 1 includes a compositionally graded buffer (CGB) 120 positioned between a substrate 110 and an overlaying semiconductor layer 130 (or multiple layers). The CGB 120 includes two or more layers (125A and 125B) where with the n^{th} layer is referred to herein as the capping layer 125N. In some embodiments of the present disclosure, a substrate 110 may be constructed of GaAs, InP, GaP, InAs, GaSb, InSb, Si, Ge, GaN, SiC, Ga₂O₃, or sapphire. As described herein, among other things, a CGB 120 may be used to bridge the gap between a first lattice constant for the substrate 110 and a second lattice constant for the desired overlaying semiconductor layer 130. In some embodiments of the present disclosure, a substrate 110 may have a lattice constant between about 3.0 Å and about 7.0 Å, and a overlaying semiconductor layer 130 may have a lattice constant between about 3.0 Å and about 7.0 Å.

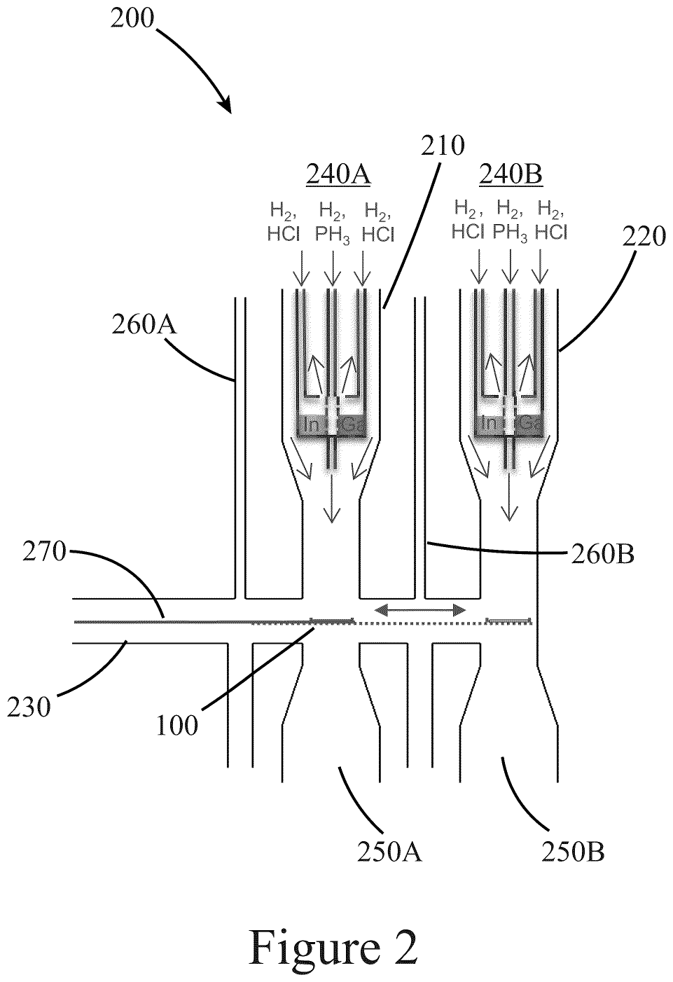

In order to bridge the difference between the lattice constant of the substrate 110 and the overlaying semiconductor layer 130, a series of individual layers 125 may be deposited on the previously presented layers 125, where each subsequent layer has a slightly different elemental composition than the prior layer, or relatively large compositional changes; e.g. from GaInP to GaInA. As described herein, these layers 125 may be deposited using a “dynamic” HVPE method, where the composition 100 is repeatedly transferred between a first chamber and a second chamber (see FIG. 2). For example, in some embodiments of the present disclosure, the layers 125 of a CGB 120 may be described by A¹ₓA²₁₋ₓB, where A¹ is a first Group III element, A² is a second Group III element and B is a Group V element, and where x is between 0 and 1, inclusively. Similarly, in some embodiments of the present disclosure, the layers 125 of a CGB 120 may be described by AB¹ₓB²₁₋ₓ, where B¹ is a first Group V element, B² is a second Group V element and A is a Group III element, and where x is between 0 and 1, inclusively. In some embodiments of the present disclosure, the individual layers 125 may include three or more elements. For either or each case, the value of x may incrementally increase for each successive layer 125 deposited in the CGB 120, or the value of x may incrementally decrease for each successive layer 125 deposited in the CGB 120. As a result of depositing such a CGB 120, the final layer, the capping layer 125N may be characterized by at least one of an improved physical property or a performance metric when compared to a CGB performed by a non-HVPE method or an HVPE method using a single chamber. In other words, each layer 125 of a CGB 120 may be constructed of an alloy that includes a first Group III element (A¹) and a first Group V element (B¹) and further includes at least one of a second Group III element (A²) and/or a second Group V element (B²), such that each layer of the CGB comprises at least one of A¹ₓA²₁₋ₓ and/or B¹ₓB²ᵢ₋ₓ.

In some embodiments of the present disclosure, each layer 125 of a CGB 120 of a composition 100 may include at least one of SiₓGe₁₋ₓ, Ga₁₋ₓInₓP, AlₓInᵢ₋ₓP, AlₓInᵢ₋ₓAs, InₓGa₁₋ₓAs, GaAsP₁₋ₓ, GaₓIn₁₋ₓN, InAsₓP₁₋ₓ, and/or GaAsₓSb₁₋ₓ. In some embodiments of the present disclosure, a composition 100 may include at least one of a third Group III element (A³) and/or a third Group V element (B³), for example, AlGaInP, AlGaInAs, GaAsPSb, or GaAsPN.

In some embodiments of the present disclosure, each layer 125 of a CGB 120 may have a thickness between about 20 nm and about 20,000 nm resulting in a total thickness of the CGB 120 between 100 nm and about 100 μm. In some embodiments of the present disclosure, the change in x, Δx, between adjacent layers 125 (e.g. 125A and 125B) may be between about 0.01 and about 0.25 as a molar fraction basis. In some embodiments of the present disclosure, the change in lattice constant between adjacent layers 125 (e.g. 125A and 125B) may be between about 0.01 Å and about 0.25 Å. An end result of depositing a CGB 120 like those described above, may be an improved physical property and/or performance metric includes at least one of a percent strain relaxation in the cap layer 125N of a CGB 120, a density of threading dislocations in the cap layer 125N, and/or a measure of a change in concentration of an element in the CGB 120 versus thickness of the CGB 120 as measured by energy dispersive x-ray spectroscopy (EDS). In some embodiments of the present disclosure, the percent strain relaxation of the cap layer 125N may be greater than about 80% or greater than about 90% or greater than about 95%. In some embodiments of the present disclosure, the density of threading locations relaxation of the cap layer 125N may be less than about 3×10\hat{ }5 cm⁻² or less than about 3×10\hat{ }6 cm⁻² or less than about 3×10\hat{ }7 cm⁻² or less than about 3×10\hat{ }8 cm⁻².

FIG. 2 illustrates aspects of an HVPE system 200 for producing a composition 100 like those described above, according to some embodiments of the present disclosure. In this example, the system 200 includes a first chamber 210 and a second chamber 220 physically connected by a transfer channel 230 and gaseously separated by a purge channel 260B through which an inert gas is flowing, thereby providing a “curtain barrier” that prevents reactants and/or byproducts produced in the first chamber 210 from migrating into the second chamber 220 and vice versa. Each chamber, the first chamber 210 and the second chamber 220 is configured to receive one or more reactant streams, 240A and 240B, respectively to provide the Group III and Group V elements needed to make the targeted composition 100. Each chamber, the first chamber 210 and the second chamber 220, is also configured with a dedicated exhaust, 250A and 250B, respectively, which allow unreacted reactants and/or byproducts to exit the system 200. As shown in FIG. 2, the composition 100, for example a substrate 110 or a substrate 110 with one or more layers 120 of CGB 120 positioned on a substrate 110 may be positioned on a moveable holder 270 configured to move the composition 100 back and forth, as many times as desired, between the first chamber 210 and the second chamber 220 (as indicated by the two-headed arrow). As shown in FIG. 2, a system 200 may also include a second purge channel 260B to prevent reactants from traveling down the transfer channel 230. Each purge channel 260 may be configured to lead to its own exhaust (not labeled). In some embodiments of the present disclosure, gaseous reactants used in an HVPEW system as described herein may include at least one of GaCl, GaCl₃, InCl, InCl₃, AlCl, AlCl₃, AsH₃, PH₃, SbH₃, NH₃, SbCl₃, AsCl₃, PCl₃, SiH₄, SiCl₄, GeH₄, and/or GeCl₄.

As shown herein, an embodiment of a CGB was synthesized that included a plurality of compressive Ga₁₋ₓInₓP layers with lattice constants between GaAs and InP by hydride vapor phase epitaxy (HVPE) at growth rates up to ˜1 μm/min and with threading dislocation densities (TDD) as low as 1.0×10⁻⁶ cm⁻². The effect of growth conditions resulting from substrate offcut direction, growth rate, and strain grading rate on CGB quality were studied. As described above “dynamic grading” using an HVPE system was utilized to create compositional interfaces via mechanical transfer of a substrate between two growth chambers, in contrast to “static grading” where the entire CGB is manufactured in a single chamber. As shown herein, dynamic grading yields smoother grades with higher relaxation compared to static grading, possibly due to the observed formation of more abrupt interfaces. As shown herein, substrate offcut direction can be an important factor for obtaining high-quality grades with low defect density. (001) substrates offcut towards (111)B yielded smoother CGBs with lower TDD compared to CGBs grown on substrates offcut towards (111)A. Transmission electron microscopy of static and dynamic CGBs grown on A and B-offcuts only found evidence of phase separation in a static A-offcut CGB, indicating that a B offcut can help to limit phase separation, which in turn can help keep TDD low. Reduced growth rates led to the development CuPt atomic ordering, which affected dislocation glide dynamics but did not significantly alter TDD. Higher growth rates led to smoother CGBs and did not appreciably increase TDD as otherwise predicted by dislocation dynamics models. These results show, among other things, HVPE's promise for lattice-mismatched applications and low-cost InP virtual substrates on GaAs.

Described herein is a study of HVPE-grown Ga₁₋ₓInₓP CGBs that bridge the lattice constant gap between GaAs and InP (3.8% mismatch), with growth rates up to −1 μm/min. The effect of growth parameters such as substrate offcut, growth rate (R_{G}), strain grading rate (R_{S}), and final indium fraction (x_{In}) on CGB defect structure were studied, with the results described herein. All materials were grown in an atmospheric pressure dual-chamber D-HVPE reactor (see FIG. 2) using PH₃ and GaCl and InCl generated in situ from elemental metals and HCl. The carrier gas used was H₂, the growth temperature was 650° C., and the group V/III ratio, defined as the ratio of the flow rates of PH₃ to HCl(Ga)+HCl(In), was 2.7 for all samples. Substrates were undoped (001) GaAs, misoriented either 4° towards the (111)B plane (4° B) or 6° towards (111)A (6° A). FIG. 2 depicts the two compositional grading strategies that were used. “Static grading” used only one growth chamber, with the HCl flows to the Ga and In boats stepped at constant intervals to increase the vapor-phase InCl/GaCl ratio as the wafer is held in place. “Dynamic grading” used both growth chambers, taking advantage of the unique capability of D-HVPE. In dynamic grading, the flows for the second step equilibrate in the second chamber while the first step grows in the first chamber. When growth of the first step is complete, the sample is mechanically transferred to the second chamber, initiating growth of the second step. Then the flows in the first growth chamber are adjusted to target a new, third step composition while the second step is growing in the second chamber. This process may be repeated until the desired structure is realized.

In all cases, the composition/device produced included a series of discrete steps with successively larger x_{In} followed by a thicker constant composition capping layer grown three times as long as the individual steps. The average R_{G} was determined by scanning electron microscopy or TEM. High resolution x-ray diffraction (XRD) reciprocal space mapping (RSM) was used to measure the composition and residual strain (C) of the capping layer. A combination of cross-sectional TEM, CL, and ECCI was used to probe the defect structure of the CGBs and determine TDD. The TEM images presented are high-angle annular dark field (HAADF) images of either [110] or [11̅0] cross-sections. Energy dispersive x-ray spectroscopy (EDS) images were taken in the TEM to analyze the compositional profiles in the CGBs. 25 μm×25 μm atomic force microscopy (AFM) scans were used to measure the root-mean-square surface roughness (R_{q}) of the CGBs.

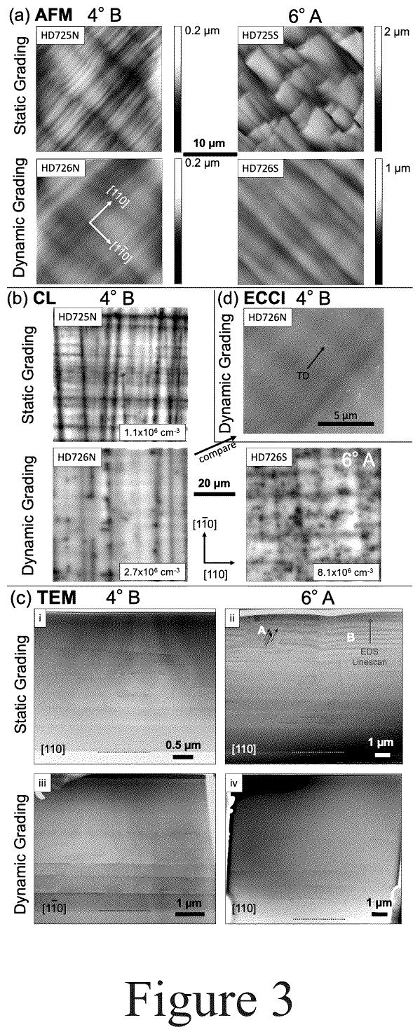

An initial set of four CGBs were grown with varying substrate offcut direction and grade style at growth rates from 40-49 μm/h. In this sample set, the 4° B and 6° A substrates were co-loaded in separate static and dynamic runs. The first four rows of Table 1 list their parameters. FIG. 3 shows, from top to bottom, AFM micrographs, CL images, and TEM images for these four samples. These results show a clear benefit to the use of 4° B substrates vs. 6° A. The 4° B CGBs were significantly smoother in both the static and dynamic cases and had significantly lower TDD, evidenced by the CL images in FIG. 3. The dynamic 6° A CGB had three times the TDD of the 4° B case. TDD in the static 6° A CGB was not measured because it was too rough. The static 4° B CGB had less than half as many dislocations as the dynamic 4° B CGB, with TDD=1.1×10⁶ cm⁻², despite being rougher. The residual strains (see Table 1) in the static grades tended to be higher. The dynamic grades tended to be smoother than the static grades, perhaps because the surfaces of the static grades roughened in response to the higher residual strain.

TABLE 1
Parameters and properties of the GaInP CGBs described herein. From left to right: sample name, substrate orientation,
grading style (static or dynamic), measured indium fraction in the capping layer, misfit relative to the substrate
(f), average growth rate (R_{G}), total thickness (t), strain grading rate (R_{S}), R_{q} from AFM, TDD from CL and ECCI,
presence of atomic ordering, residual strain in the cap layer (ε) in the [100] and [11̅0] directions, epilayer
tilt toward [11̅1], and the percentage of dislocations on the [11̅1] plane calculated from the tilt.

| | | | | | | | | | CL | ECCI | | | | | Disloc. on |
|---|---|---|---|---|---|---|---|---|---|---|---|---|---|---|---|
| | | | | | Avg. | | | | TDD | TDD | | ε | ε | [11̅1] | (11̅1) |
| | | Style | | f | R_{G} | t | R_{S} | R_{q} | 10⁶ | 10⁶ | | [110] | [11̅0] | Tilt | plane |
| Sample | Sub. | S/D | x_{In} | % | μm/h | μm | %/μm | nm | cm⁻² | cm⁻² | Order? | % | % | arcsec | % |
| HD725N | 4B | S | 0.69 | 1.54 | 41 | 5.3 | 0.45 | 11 | 1.1 | | n | −0.24 | −0.63 | −1318 | 42% |
| HD725S | 6A | S | 0.69 | 1.51 | 49 | 5.3 | 0.37 | 97.8 | | | n | −0.23 | −0.17 | −572 | 53% |
| HD726N | 4B | D | 0.75 | 1.96 | 40 | 5.1 | 0.59 | 6.8 | 2.7 | 4.1 | n | −0.38 | −0.06 | 1178 | 60% |
| HD726S | 6A | D | 0.73 | 1.85 | 48 | 5.8 | 0.46 | 24.4 | 8.1 | | n | −0.16 | −0.18 | −1444 | 48% |
| HE577 | 4B | S | 0.96 | 3.53 | 57 | 11.4 | 0.46 | 9.8 | 2.4 | | n | −0.04 | −0.15 | −364 | 48% |
| HD848 | 4B | S | 0.63 | 1.09 | 20 | 1.9 | 0.64 | 6.8 | 1.0 | 1.5 | y | −0.32 | −0.51 | 2343 | 87% |
| HD849 | 4B | S | 0.69 | 1.51 | 19 | 0.8 | 1.87 | 7.0 | 2.1 | | y | −0.53 | −0.58 | 3194 | 86% |
| HD989 | 4B | D | 0.83 | 2.58 | 30 | 5.2 | 0.54 | 9.8 | 1.3 | 1.5 | y | −0.33 | −0.05 | 4000 | 77% |

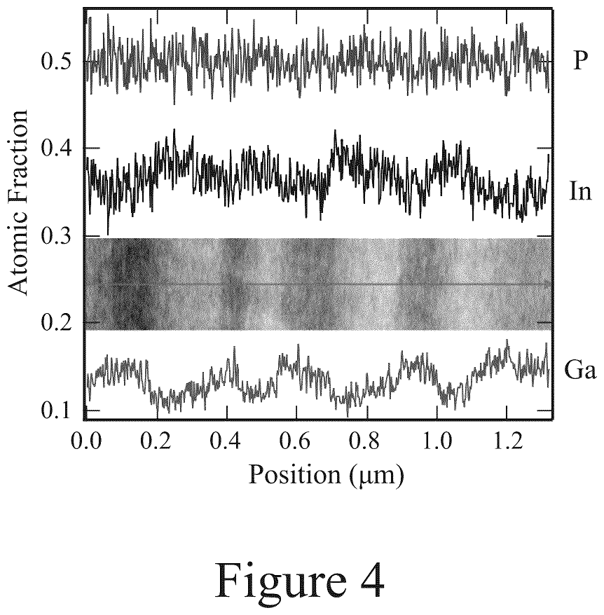

The TEM images exhibit the typical defect structure of step-graded buffers, with misfit dislocations generally confined to the interfaces between steps. There is evidence of gross phase separation only in the 6° A static grade, which exhibits multiple regions of contrast in the HAADF image. There are bright lines of contrast ordered near-vertically in the upper left region ‘A’, and lamellae of light and dark contrast oriented roughly parallel to the substrate/epilayer interface in region ‘B’. An EDS line-scan in region B was performed, delineated by the red arrow in FIG. 3 and presented in FIG. 4, to investigate the origin of the contrast in the image. There are clear fluctuations in the Ga and In atomic fractions. These fluctuations correlate with the light and dark regions in the TEM image because there is a direct relationship between atomic mass and brightness in dark-field imaging. The atomic fractions of Ga and In vary by ±0.04, corresponding to compositions of Ga_{0.22}In_{0.78}P in the In-rich regions and Ga_{0.30}In_{0.70}P in the In-poor regions. This phase separation does not set in until later in the grade and is correlated with the extreme roughness measured in this sample. It is not clear whether the roughening induces the phase separation or vice-versa.

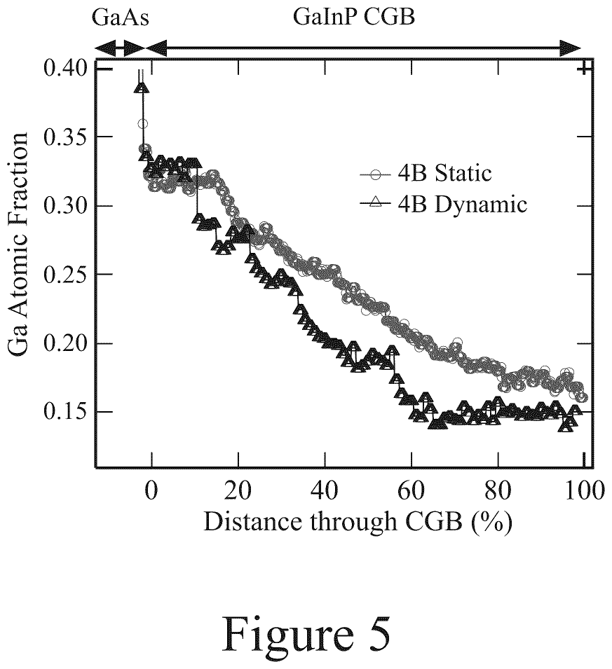

EDS was performed on the 4° B static and dynamic CGBs to understand the effect of grading style on the composition profile. FIG. 5 shows linescans of the Ga atomic fraction as a function of position. The Ga fraction in the static CGB decreases almost linearly, appearing as if a continuous-rather than the intended step-grading scheme was employed. In contrast, the Ga-profile of the dynamic CGB exhibits more discrete changes in Ga fraction. These profiles suggest that it takes longer than the 60 second step duration for the Ga and In sources to achieve steady state when the HCl flow rates are stepped in the static CGBs. The flows for each step in the dynamic grade are given 60 second to equilibrate and, while the steps are not perfectly abrupt, the abruptness is significantly increased compared to the static grade case. It may be theorized that the more abrupt compositional shifts afforded by dynamic grading provides more driving force for dislocation glide, leading to the reduced residual strain observed in those grades (see Table 1).

Next, CGBs with higher and lower growth rates were deposited on 4° B substrates to determine how growth rate affects CGB quality. HE577 is a static CGB grown with R_{G}=57 μm/h, x_{In} of 0.95, and roughly the same strain grading rate as the initial set of samples. The TDD was 2.4×10⁶ cm⁻² and R_{q}=9.8 nm, showing that the grade quality has not significantly degraded despite the increase in growth rate and x_{In}.

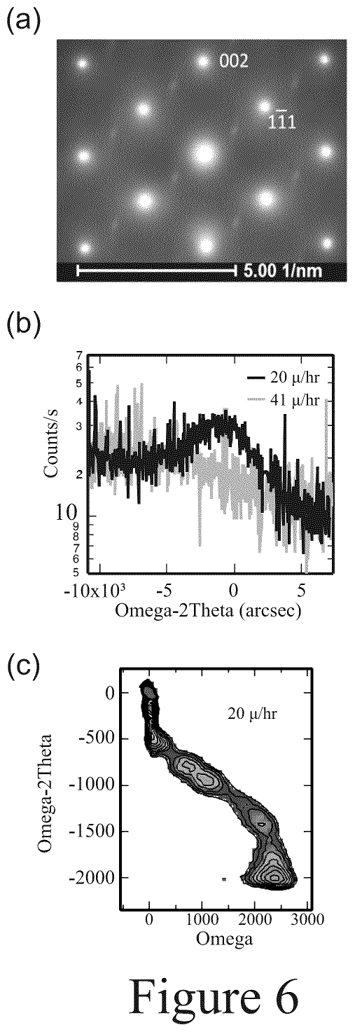

HD848 and 849 are static grades with reduced growth rates of ˜20 μm/h. Reduction of the growth rate formed CuPt-type atomic ordering in these CGBs. CuPt ordering can occur in lattice-matched GaInP epilayers grown by HVPE, and can influence dislocation nucleation and glide dynamics in OMVPE-grown CGBs. CuPt ordering can create a superlattice of alternating InP and GaP {111} planes, which can be detected by diffraction. Panel a of FIG. 6 shows a TEM selected area diffraction pattern of HD848 revealing single-variant ordering on the 1/2{11̅1} family of planes. Panel b of FIG. 6 compares XRD scans of the (1/2,1̅/2,3/2) superlattice reflection of HD848 and HD725N, which was grown at 41 μm/h. The lower growth rate sample possesses a well-defined (1/2,1̅/2,3/2) peak but no peak appears for the higher growth rate sample. These results are consistent with prior work that showed that increased growth rate eliminated ordering in HVPE-grown lattice-matched GaInP epilayers. The presence of ordering in the lower growth rate CGBs affects their distributions of misfit dislocations. Panel c of FIG. 6 shows a (004) RSM of HD848 taken with the beam incident along [11̅0] exhibiting a positive tilt of +2343 arcseconds in Omega. Ordering induces a strong positive tilt by biasing the populations of dislocations lying in the (11̅1) vs. (1̅11) planes, which can relieve equal amounts of strain but have opposite tilt components. In the absence of ordering, CGBs can have low tilt, meaning that the populations of misfit dislocations on each plane are balanced, or negative tilt, due to the effect of the offcut. The distribution of dislocations were calculated from the tilt and total misfit relieved and are listed in Table 1.87% of [110]-aligned dislocations in HD848 lie on the (11̅1) plane, and only 13% on the (1̅11) plane, while none of the higher growth rate samples have more than 60% of dislocations in either plane. Ordering can enhance dislocation glide, potentially leading to reduced TDD, but it is unclear how beneficial the presence of ordering is here. This ordered grade has a CL TDD ˜1×10⁶ cm⁻², which is roughly the same as the higher growth rate static grade on 4B. The strain grading rate for this sample was 0.64%/μm and increasing this parameter by a factor of ˜3 to 1.87%/μm only led to a doubling of TDD to 2.1×10⁶ cm⁻² as indicated in Table 1.

In addition, a dynamic CGB was grown using a reduced growth rate (HD989) to determine if dynamic grading affects ordering. x_{In} was 0.81, which approximately corresponds to the lattice constant required for a ˜1 eV GaInAs subcell in an optimized triple junction solar cell with GaInP top and GaAs middle junctions. This sample exhibited ordering as judged by the strong positive tilt toward [11̅1], indicating that the ordering is maintained even as the sample is transferred back and forth between chambers. TDD was 1.3×10⁶ cm⁻³ a low value given the 2.58% lattice mismatch. This grade is also highly relaxed, with residual strains of −0.33% (86% relaxed) in the [110] and −0.048% (98% relaxed) in the [11̅0] direction, providing further evidence suggesting that dynamic grading increases relaxation.

Variation of parameters including grading style, offcut, and growth rate all impact aspects of CGB quality. Generally, low-TDD grades were grown herein, under most conditions, but some parameters were particularly important. Dynamic grading led to reduced surface roughness and improved strain relaxation relative to static grading, but both styles achieved comparably low TDD. The substrate offcut strongly influenced CGB quality, with 4° B CGBs exhibiting improved properties vs. 6° A CGBs. The 4° B CGBs did not exhibit phase separation in any case, whereas there was phase separation in the 6° A static CGB. Order-enhanced glide was not necessary to obtain low TDD in our HVPE CGBs because CGBs grown with and without ordering exhibited low TDD. This finding suggests that some property of the B-offcut separate from, but possibly related to, the induction of ordering makes the use of B-offcuts beneficial. One possibility is that the B-offcut surface reconstruction that induces long-range ordering also limits surface diffusion and prevents phase separation, which is a surface-driven process. The prevention of phase separation is important to achieving long dislocation glide length and low TDD in graded materials.

The high growth rates employed here were not correlated with higher defect densities, even though dislocation dynamics models predict a linear dependence of TDD on both R_{G} and R_{S}. TDD<3×10⁶ cm⁻² was achieved for grades grown at rates from 19-57 μm/h, with no obvious degradation with higher growth rates. Notably, increasing the R_{S} by a factor of three only led to a factor of two increase in TDD (compare HD848 vs. HD849), implying that the R_{S} was not essential to obtaining low TDD. There is evidence that larger R_{G} may in fact improve CGB quality by suppressing surface roughness and phase separation, which are two factors linked to higher TDD. For example, HE577, a static grade to x_{In}=0.96, is smoother than HD725N (static grade, x_{In}=0.69) despite grading to a larger lattice constant with a similar R_{S} and being significantly thicker. This result may be attributed to the faster R_{G}, which likely limits adatom diffusion lengths and minimizes roughening. Similarly, high R_{G} previously was shown to prevent the formation of CuPt ordering, another process driven by surface diffusion kinetics. By extension, it may be suspected that higher HVPE R_{G}s suppress phase separation by limiting adatom diffusion. This is supported by the fact that the dynamic 6° A CGB did not phase separate when that would normally be expected based on the offcut. This CGB does have higher TDD than any of the 4° B CGBs, suggesting that there may be some small-scale phase separation we could not detect in TEM leading to higher TDD. The static 6° A CGB did phase separate, indicating the conditions used were close to a tipping point for phase separation on 6° A and small changes in growth conditions can cause gross phase separation to occur. The combination of high growth rates and B-offcut substrates provides the best resistance to phase separation, enabling low-defect CGBs.

In summary, Ga₁₋ₓInₓP CGBs were grown by HVPE on GaAs over a wide range of lattice constants between GaAs and InP, with growth rates up to −1 μm/min. TDD as low as 1.0×10⁶ cm⁻² was achieved. Substrate offcut direction strongly affected the CGB defect structure, with offcut towards (111)B planes helping to reduce TDD, surface roughness, and phase separation. Static and dynamic grading schemes were tested with slight benefit demonstrated for dynamic grading, via more abrupt compositional profiles. Higher growth rate CGBs were smoother, while lower growth rate CGBs exhibited atomic ordering and order-enhanced glide, but overall TDD did not correlate with growth rate. These results demonstrate the potential for D-HVPE to achieve significant cost reduction of metamorphic III-V devices via increased throughput and decreased capital intensity.

The present disclosure may be further understood by the following non-limiting examples:

Example 1. A composition comprising:
a substrate comprising GaAs or InP;
a compositionally graded buffer (CGB) comprising a plurality of layers, wherein:
each layer of the CGB comprises an alloy comprising a first Group III element (A¹) and a first Group V element (B¹),
each layer of the CGB further comprises at least one of a second Group III element (A²) or a second Group V element (B²), such that each layer of the CGB comprises at least one of A¹ₓA²₁₋ₓ or B¹ₓB²₁₋ₓ,
each subsequent layer of the CGB, relative to the substrate, has a value for x that is different than a value of x for the previously deposited layer, x is between 0 and 1.0, inclusively, where x either increases for each subsequent layer or x decreases for each subsequent layer, and
at least one layer of the CGB is characterized by at least one of an improved physical property or a performance metric when compared to a CGB performed by a non-HVPE method or an HVPE method using a single chamber.

Example 2. The composition of example 1, wherein the alloy comprises a ternary alloy.

Example 3. The composition of example 1 or 2, wherein the alloy comprises at least one of Ga₁₋ₓInₓP, InₓGa₁₋ₓAs, GaAsP₁₋ₓ, InAsₓP₁₋ₓ, or GaAsₓSb₁₋ₓ.

Example 4. The composition of any of examples 1-3, wherein the alloy further comprises at least one of a third Group III element (A³) or a third Group V element (B³).

Example 5. The composition of any of examples 1-4, wherein the improved physical property or performance metric includes at least one of a percent strain relaxation in a cap layer of the CGB, a density of threading dislocations in the cap layer, or a measure of a change in concentration of an element in the CGB versus thickness of the CGB as measured by energy dispersive x-ray spectroscopy (EDS).

Example 6. The composition of example 5, wherein the percent strain relaxation is greater than about 80% or greater than about 90% or greater than about 95%.

Example 7. The composition of example 5 or 6, wherein the density of threading locations is less than about 3×10\hat{ }5 cm⁻² or less than about 3×10\hat{ }6 cm⁻² or less than about 3×10\hat{ }7 cm⁻² or less than about 3×10\hat{ }8 cm⁻².

Example 8. A method for producing a compositionally graded buffer (CGB) by hydride vapor phase epitaxy (HVPE), the method comprising:
providing a device configured to perform HVPE, the device comprising:
a substrate comprising GaAs or InP;
a first chamber; and
a second chamber, wherein:
the substrate is configured to move repeatedly from the first chamber to the second chamber and from the second chamber to the first chamber;
sequentially depositing a plurality of layers resulting in the forming of the CGB, wherein:
at least one layer of the CGB is deposited in the first chamber,
at least one layer of the CGB is deposited in the second chamber.

Example 9. The method of example 8, wherein:
each layer of the CGB comprises an alloy comprising a first Group III element (A¹) and a first Group V element (B¹),
each layer of the CGB further comprises at least one of a second Group III element (A²) or a second Group V element (B²), such that each layer of the CGB comprises at least one of A¹ₓA²₁₋ₓ or B¹ₓB²₁₋ₓ, and
each subsequent layer of the CGB, relative to the substrate, has a value for x that is different than a value of x for the previously deposited layer, x is between 0 and 1.0, inclusively, where x either increases for each subsequent layer or x decreases for each subsequent layer.

Example 10. The method of example 9, wherein the alloy comprises a ternary alloy.

Example 11. The method of example 9 or 10, wherein the alloy comprises at least one of Ga₁₋ₓInₓP, InₓGa₁₋ₓAs, GaAsP₁₋ₓ, InAsₓP₁₋ₓ, or GaAsₓSb₁₋ₓ.

Example 12. The method of any of examples 9-11, wherein the alloy further comprises at least one of a third Group III element (A³) or a third Group V element (B³).

Example 13. The method of claim 8, wherein at least one layer of the CGB is characterized by an improved physical property or performance metric when compared to a CGB performed by a non-HVPE method or an HVPE method using a single chamber.

Example 14. The method of example 13, wherein the improved physical property or performance metric includes at least one of a percent strain relaxation in a cap layer of the CGB, a density of threading dislocations in the cap layer, or a measure of a change in concentration of an element in the CGB versus thickness of the CGB as measured by energy dispersive x-ray spectroscopy (EDS).

Example 15. The method of example 14, wherein the percent strain relaxation is greater than about 80% or greater than about 90% or greater than about 95%.

Example 16. The method of example 14 or 15, wherein the density of threading locations is less than about 3×10\hat{ }5 cm⁻² or less than about 3×10\hat{ }6 cm⁻² or less than about 3×10\hat{ }7 cm⁻² or less than about 3×10\hat{ }8 cm⁻².

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, are disclosed separately. When a Markush group or other grouping is used herein, all individual members of the group and all combinations and subcombinations possible of the group are intended to be individually included in the disclosure. For example, when a device is set forth disclosing a range of materials, device components, and/or device configurations, the description is intended to include specific reference of each combination and/or variation corresponding to the disclosed range.

Every formulation or combination of components described or exemplified herein can be used to practice the invention, unless otherwise stated.

Whenever a range is given in the specification, for example, a density range, a number range, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter are claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

What is claimed is:

1. A composition comprising:
a substrate comprising GaAs or InP;
a compositionally graded buffer (CGB) comprising a plurality of layers, wherein:
each layer of the CGB comprises an alloy comprising a first Group III element (A¹) and a first Group V element (B¹),
each layer of the CGB further comprises at least one of a second Group III element (A²) or a second Group V element (B²), such that each layer of the CGB comprises at least one of A¹ₓA²₁₋ₓ or B¹ₓB²₁₋ₓ,
each subsequent layer of the CGB, relative to the substrate, has a value for x that is different than a value of x for the previously deposited layer, x is between 0 and 1.0, inclusively, where x either increases for each subsequent layer or x decreases for each subsequent layer, and
at least one layer of the CGB is characterized by at least one of an improved physical property or a performance metric when compared to a CGB performed by a non-HVPE method or an HVPE method using a single chamber.

2. The composition of claim 1, wherein the alloy comprises a ternary alloy.

3. The composition of claim 2, wherein the alloy comprises at least one of Ga₁₋ₓInₓP, InₓGa₁₋ₓAs, GaAsP₁₋ₓ, InAsₓP₁₋ₓ, or GaAsₓSb₁₋ₓ.

4. The composition of claim 1, wherein the alloy further comprises at least one of a third Group III element (A³) or a third Group V element (B³).

5. The composition of claim 1, wherein the improved physical property or performance metric includes at least one of a percent strain relaxation in a cap layer of the CGB, a density of threading dislocations in the cap layer, or a measure of a change in concentration of an element in the CGB versus thickness of the CGB as measured by energy dispersive x-ray spectroscopy (EDS).

6. The composition of claim 5, wherein the percent strain relaxation is greater than about 80% or greater than about 90% or greater than about 95%.

7. The composition of claim 5, wherein the density of threading locations is less than about 3×10\hat{ }5 cm⁻² or less than about 3×10\hat{ }6 cm⁻² or less than about 3×10\hat{ }7 cm⁻² or less than about 3×10\hat{ }8 cm⁻².

8. A method for producing a compositionally graded buffer (CGB) by hydride vapor phase epitaxy (HVPE), the method comprising:
providing a device configured to perform HVPE, the device comprising:
a substrate comprising GaAs or InP;
a first chamber; and
a second chamber, wherein:
the substrate is configured to move repeatedly from the first chamber to the second chamber and from the second chamber to the first chamber;
sequentially depositing a plurality of layers resulting in the forming of the CGB, wherein:
at least one layer of the CGB is deposited in the first chamber,
at least one layer of the CGB is deposited in the second chamber.

9. The method of claim 8, wherein:
each layer of the CGB comprises an alloy comprising a first Group III element (A¹) and a first Group V element (B¹),
each layer of the CGB further comprises at least one of a second Group III element (A²) or a second Group V element (B²), such that each layer of the CGB comprises at least one of A¹ₓA²₁₋ₓ or B¹ₓB²₁₋ₓ, and
each subsequent layer of the CGB, relative to the substrate, has a value for x that is different than a value of x for the previously deposited layer, x is between 0 and 1.0, inclusively, where x either increases for each subsequent layer or x decreases for each subsequent layer.

10. The method of claim 9, wherein the alloy comprises a ternary alloy.

11. The method of claim 9, wherein the alloy comprises at least one of Ga₁₋ₓInₓP, InₓGa₁₋ₓAs, GaAsP₁₋ₓ, InAsₓP₁₋ₓ, or GaAsₓSb₁₋ₓ.

12. The method of claim 9, wherein the alloy further comprises at least one of a third Group III element (A³) or a third Group V element (B³).

13. The method of claim 8, wherein at least one layer of the CGB is characterized by an improved physical property or performance metric when compared to a CGB performed by a non-HVPE method or an HVPE method using a single chamber.

14. The method of claim 13, wherein the improved physical property or performance metric includes at least one of a percent strain relaxation in a cap layer of the CGB, a density of threading dislocations in the cap layer, or a measure of a change in concentration of an element in the CGB versus thickness of the CGB as measured by energy dispersive x-ray spectroscopy (EDS).

15. The method of claim 14, wherein the percent strain relaxation is greater than about 80% or greater than about 90% or greater than about 95%.

16. The method of claim 14, wherein the density of threading locations is less than about 3×10\hat{ }5 cm⁻² or less than about 3×10\hat{ }6 cm⁻² or less than about 3×10\hat{ }7 cm⁻² or less than about 3×10\hat{ }8 cm⁻².
